(19) United States
(12) Patent Application Publication
(10) Pub. No.: US 2026/0223634 A1
(43) Pub. Date: Jul. 30, 2026

(54) ELECTROSTATIC CHUCK DEVICE

(71) Applicant: SUMITOMO OSAKA CEMENT CO., LTD., Tokyo (JP)

(72) Inventors: Satoyoshi INUI, Tokyo (JP); Yuuki KINPARA, Tokyo (JP); Taku ICHIYOSHI, Tokyo (JP); Toru SUGAMATA, Tokyo (JP)

(73) Assignee: SUMITOMO OSAKA CEMENT CO., LTD., Tokyo (JP)

(21) Appl. No.: 19/143,901

(22) PCT Filed: Dec. 18, 2023
(86) PCT No.: PCT/JP2023/045223

§ 371 Date: Jun. 27, 2025

(30) Foreign Application Priority Data
Dec. 27, 2022 (JP) 2022-209541

(51) Int. Cl. H10P 72/72; H01J 37/32

(52) U.S. Cl. CPC H10P 72/722; H01J 37/32715; H01J 2237/2007

(57) ABSTRACT

An electrostatic chuck device includes: an electrostatic chuck portion which supports a plate-shaped sample on a placement surface facing one side in a thickness direction and in which an internal electrode for electrostatic adsorption is built-in; a base portion that supports the electrostatic chuck portion from the other side in the thickness direction and cools the electrostatic chuck portion; an adhesive layer that is located between the electrostatic chuck portion and the base portion and includes a first adhesive portion that fixes the electrostatic chuck portion and the base portion; and a an insulator. The electrostatic chuck portion has a first through-hole, the base portion has a second through-hole communicating with the first through-hole, the insulator is disposed in the second through-hole, the base portion has a facing surface and a curved surface located at an opening of the second through-hole and connected to the facing surface.

### TECHNICAL FIELD

The present invention relates to an electrostatic chuck device.

This application claims priority based on Japanese Patent Application No. 2022-209541 filed on Dec. 27, 2022, the content of which is incorporated herein by reference.

### BACKGROUND ART

In a semiconductor manufacturing apparatus, an electrostatic chuck device that fixes a plate-shaped sample such as a wafer or a glass substrate to a chuck surface is used. The electrostatic chuck device includes an electrostatic chuck portion that includes an electrostatic adsorption mechanism, a base portion that cools the electrostatic chuck portion, and an adhesive layer that adheres the electrostatic chuck portion to the base portion. Such an electrostatic chuck device is provided with a through-hole for introducing a cooling gas (for example, Patent Literature No. 1).

### CITATION LIST

### Patent Literature

Patent Literature No. 1: Japanese Laid-open Patent Publication No. 2004-31665

### SUMMARY OF INVENTION

### Technical Problem

In order to increase cooling efficiency by a cooling gas, for example, it is considered to increase a size of a through-hole to increase the amount of heat absorbed by the cooling gas in the base portion. However, in this case, there is a problem in that discharge from the base portion or the electrostatic chuck portion is likely to occur due to the increase in size of the through-hole, or the like. That is, in order to improve the cooling efficiency of the plate-shaped sample by the cooling gas, it is necessary to solve such a problem.

The present invention has been made in view of such circumstances, and an object of the present invention is to provide an electrostatic chuck device in which discharge is suppressed and cooling efficiency is improved.

### Solution to Problem

In order to achieve the above-described object, one aspect of the present invention includes the following aspects. In the following inventions, two or more may be combined with each other.
[1] An electrostatic chuck device including: a plate-shaped electrostatic chuck portion which supports a plate-shaped sample on a placement surface facing one side in a thickness direction and in which an internal electrode for electrostatic adsorption is built-in; a base portion that supports the electrostatic chuck portion from an other side in the thickness direction and cools the electrostatic chuck portion; an adhesive layer that is located between the electrostatic chuck portion and the base portion and includes a first adhesive portion that fixes the electrostatic chuck portion and the base portion; and a tubular insulator, in which the electrostatic chuck portion is provided with a first through-hole extending along the thickness direction, the base portion is provided with a second through-hole extending along the thickness direction and communicating with the first through-hole, the insulator is disposed in the second through-hole, the base portion has a facing surface facing the electrostatic chuck portion, and the base portion has a curved surface that is located at an opening of the second through-hole and is connected to the facing surface.
[2] The electrostatic chuck device according to [1], in which a radius of curvature of the curved surface in a cross-section along a central axis line of the second through-hole is larger than a thickness dimension of the internal electrode for electrostatic adsorption.
[3] The electrostatic chuck device according to [1] or [2], in which a radius of curvature of the curved surface in a cross-section along a central axis line of the second through-hole is larger than a thickness dimension of the first adhesive portion.
[4] The electrostatic chuck device according to any one of [1] to [3], in which a radius of curvature of the curved surface in a cross-section along a central axis line of the second through-hole is 10 μm or more.
[5] The electrostatic chuck device according to any one of [1] to [4], in which the adhesive layer covers the entire curved surface.
[6] The electrostatic chuck device according to [5], in which an end surface of the insulator on the one side in the thickness direction is located on the other side in the thickness direction with respect to the curved surface and an end portion of the second through-hole on the other side in the thickness direction, and the adhesive layer includes a second adhesive portion that is located between the end surface of the insulator and the electrostatic chuck portion.
[7] The electrostatic chuck device according to [6], in which a thickness dimension of the second adhesive portion is twice or more a thickness dimension of the first adhesive portion.
[8] The electrostatic chuck device according to [6] or [7], in which a dimension of the second adhesive portion in a radial direction of the second through-hole is larger than the thickness of the first adhesive portion.
[9] The electrostatic chuck device according to any one of [5] to [8], in which the adhesive layer includes a third adhesive portion that is interposed between an inner peripheral surface of the second through-hole and an outer peripheral surface of the insulator and that fixes the insulator to the inner peripheral surface of the second through-hole.
[10] The electrostatic chuck device according to any one of [1] to [9], in which a volume inside the insulator is 5 or more times a volume inside the first through-hole.
[11] The electrostatic chuck device according to any one of [1] to [10], in which arithmetic average roughness Ra of an inner peripheral surface of the insulator is larger than arithmetic average roughness Ra of an inner peripheral surface of the first through-hole.
[12] The electrostatic chuck device according to [11], in which the arithmetic average roughness Ra of the inner peripheral surface of the insulator is twice or more the arithmetic average roughness Ra of the inner peripheral surface of the first through-hole.
[13] The electrostatic chuck device according to [11] or [12], in which the arithmetic average roughness Ra of the inner peripheral surface of the insulator is 1.5 μm or more, and the arithmetic average roughness Ra of the inner peripheral surface of the first through-hole is 0.5 μm or less.
[14] The electrostatic chuck device according to any one of [1] to [13], in which a tapered surface of which a diameter decreases toward the one side in the thickness direction is provided on an inner peripheral surface of the insulator.
[15] The electrostatic chuck device according to any one of [1] to [14], in which a chamfered portion is provided at a boundary portion between the facing surface and an inner peripheral surface of the second through-hole, and the curved surface is connected to the facing surface and the chamfered portion.

### Effects of Invention

According to the present invention, it is possible to provide an electrostatic chuck device in which discharge is suppressed and cooling efficiency is improved.

### BRIEF DESCRIPTION OF DRAWINGS

FIG. 1 is a schematic cross-sectional view representing an example of an electrostatic chuck device of a first embodiment.

FIG. 2 is a schematic enlarged view of a region II in FIG. 1.

FIG. 3 is a schematic cross-sectional view representing a modification example of a curved surface that can be employed in the first embodiment.

FIG. 4 is a schematic explanatory view representing an example of a semiconductor manufacturing apparatus according to the first embodiment.

FIG. 5 is a schematic enlarged cross-sectional view representing an example of an electrostatic chuck device of a second embodiment.

FIG. 6 is a schematic enlarged cross-sectional view representing an example of an electrostatic chuck device of a third embodiment.

FIG. 7 is a schematic enlarged cross-sectional view representing an example of an electrostatic chuck device of a fourth embodiment.

FIG. 8 is a schematic enlarged cross-sectional view representing an example of an electrostatic chuck device of a fifth embodiment.

FIG. 9 is a schematic enlarged cross-sectional view representing an electrostatic chuck device of a modification example of the fifth embodiment.

### DESCRIPTION OF EMBODIMENTS

Hereinafter, examples of embodiments of the present invention will be described with reference to the drawings. It is noted that in the drawings used in the following description, a portion that is a feature is enlarged for convenience of understanding of the feature in some cases, and a dimensional ratio and the like of each constituent element are not necessarily the same as the actual values.

### First Embodiment

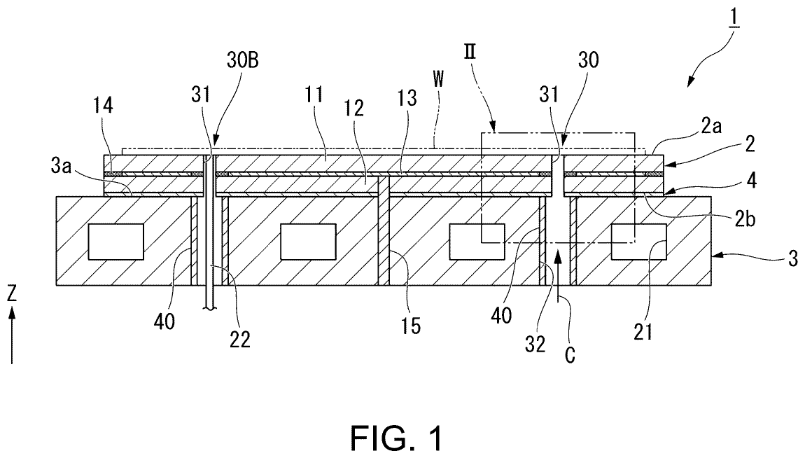

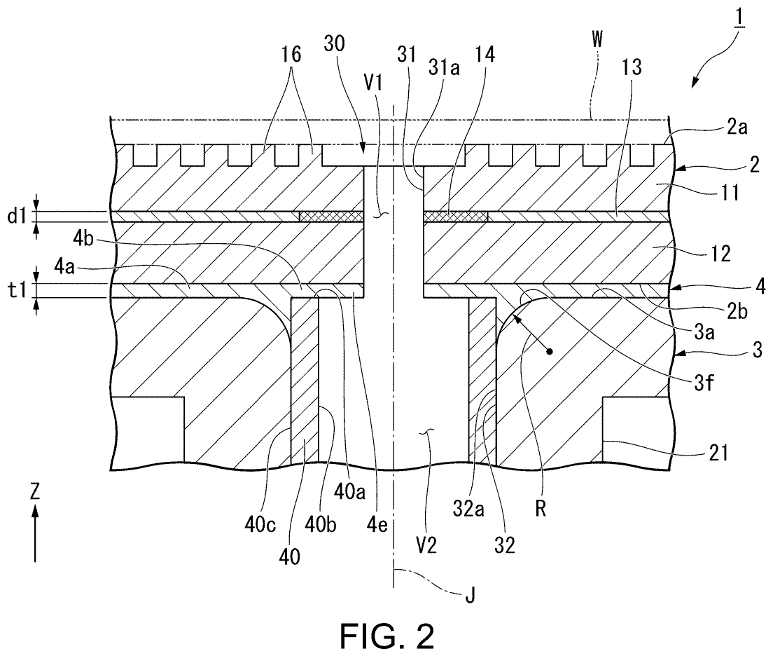

FIG. 1 is a cross-sectional view of an electrostatic chuck device 1 of a first embodiment. In addition, FIG. 2 is an enlarged view of a region II in FIG. 1.

The electrostatic chuck device 1 includes an electrostatic chuck portion 2, a base portion 3, an adhesive layer 4, and an insulator 40. The electrostatic chuck portion 2 has a plate shape and supports a plate-shaped sample W on a placement surface 2a facing one side in a thickness direction Z. The electrostatic chuck portion 2 adsorbs the plate-shaped sample W by an internal electrode 13 for electrostatic adsorption which is built-in. The base portion 3 supports the electrostatic chuck portion 2 from an other side in the thickness direction Z. The base portion 3 cools the electrostatic chuck portion 2. The adhesive layer 4 is located between the electrostatic chuck portion 2 and the base portion 3. The insulator 40 has a tubular shape and is fixed to the base portion 3.

Hereinafter, each portion of the electrostatic chuck device 1 of the present embodiment will be described in detail.

In the present specification, each portion will be described based on the thickness direction Z of the electrostatic chuck portion 2. That is, a direction in which the placement surface 2a of the electrostatic chuck portion 2 faces is referred to as one side of the thickness direction Z, and the opposite side thereof is referred to as the other side in the thickness direction. In addition, in the present specification, a relative positional relationship of the electrostatic chuck device 1 may be described in a posture in which the one side in the thickness direction Z faces upward. An upper and lower direction in the following description is a direction in an example of a posture of the electrostatic chuck device 1 during use, and does not limit the posture of the electrostatic chuck device 1 during use.

### Electrostatic Chuck Portion

The electrostatic chuck portion 2 has a structure in which a placement plate 11, the internal electrode 13 for electrostatic adsorption, and an insulating material layer 14 that surrounds a peripheral edge portion of the internal electrode 13 for electrostatic adsorption, and a supporting plate 12 are laminated in this order from the upper side. In addition, the electrostatic chuck portion 2 includes a power supply terminal 15 that passes through the adhesive layer 4 and the base portion 3 and applies a voltage to the internal electrode 13 for electrostatic adsorption.

The electrostatic chuck portion 2 includes a placement plate 11 having a circular shape in plan view, which has a placement surface 2a for placing a plate-shaped sample W such as a semiconductor wafer on an upper surface, a circular supporting plate 12 that is disposed to face a lower surface side of the placement plate 11, a circular internal electrode 13 for electrostatic adsorption that is sandwiched between the placement plate 11 and the supporting plate 12 and has a diameter smaller than that of the placement plate 11 and the supporting plate 12, and a power supply terminal 15 that is connected to a lower surface of the internal electrode 13 for electrostatic adsorption and applies a direct current voltage.

The placement plate 11 and the supporting plate 12 are made of insulating ceramic sintered bodies having mechanical strength and durability against corrosive gases and plasma thereof such as an aluminum oxide-silicon carbide (Al₂O₃—SiC) composite sintered body, an aluminum oxide (Al₂O₃) sintered body, an aluminum nitride (AlN) sintered body, and an yttrium oxide (Y₂O₃) sintered body. Since the placement plate 11 constitutes the placement surface 2a on the upper side, it is preferable that the placement plate 11 is made of a material having a particularly high dielectric constant and not containing impurities with respect to the plate-shaped sample W that is electrostatically adsorbed. From such a viewpoint, as a constituent material of the placement plate 11, it is preferable to employ a silicon carbide-aluminum oxide composite sintered body containing 4% by weight or more and 20% by weight or less of silicon carbide and containing aluminum oxide as the remainder. The materials of the placement plate 11 and the supporting plate 12 may be the same, may be different, or at least a part thereof may be different, but are preferably the same.

As shown in FIG. 2, a plurality of protrusion portions 16 having a diameter smaller than the thickness of the plate-shaped sample W are formed on the placement surface 2a of the placement plate 11, and these protrusion portions 16 support the plate-shaped sample W.

The internal electrode 13 for electrostatic adsorption is located on a lower side of the placement plate 11. The internal electrode 13 for electrostatic adsorption is used as an electrostatic chucking electrode for generating electric charges and fixing the plate-shaped sample W with an electrostatic adsorption force, and a shape or a size thereof is appropriately adjusted according to the use thereof. For example, the internal electrode 13 for electrostatic adsorption is provided as an electrode having a predetermined pattern in a layer where the internal electrode 13 for electrostatic adsorption is formed, for example, on a surface at a position where the internal electrode 13 for electrostatic adsorption is formed. It is noted that the internal electrode 13 for electrostatic adsorption may also function even when being provided as a so-called solid electrode that does not have a pattern.

The internal electrode 13 for electrostatic adsorption can be formed by forming a metal foil on the supporting plate 12 by sputtering or vapor deposition. As another example, a compound material of a conductive material which is a material for forming the internal electrode 13 for electrostatic adsorption and an organic substance can be formed by applying the compound material by using a coating method such as screen printing.

The internal electrode 13 for electrostatic adsorption is preferably formed of conductive ceramics such as an aluminum oxide-tantalum carbide (Al₂O₃—Ta₄C₅) conductive composite sintered body, an aluminum oxide-tungsten (Al₂O₃—W) conductive composite sintered body, an aluminum oxide-silicon carbide (Al₂O₃—SiC) conductive composite sintered body, an aluminum nitride-tungsten (AlN—W) conductive composite sintered body, an aluminum nitride-tantalum (AlN—Ta) conductive composite sintered body, an yttrium oxide-molybdenum (Y₂O₃—Mo) conductive composite sintered body, or a high-melting-point metal such as tungsten (W), tantalum (Ta), or molybdenum (Mo). In addition, the internal electrode 13 for electrostatic adsorption can also be formed of copper (Cu), aluminum (Al), or carbon (C). A thickness dimension d1 of the internal electrode 13 for electrostatic adsorption is not particularly limited, but is often selected from 3 μm or more and 200 μm or less, and more preferably 10 μm or more and 100 μm or less. The thickness dimension d1 may be 20 μm or more and 80 μm or less, 40 μm or more and 60 μm or less, or the like.

The insulating material layer 14 joins the placement plate 11 and the supporting plate 12 to each other and protects the internal electrode 13 for electrostatic adsorption from plasma. As a material constituting the insulating material layer 14, it is preferable to include or use the same insulating material as in main components of the placement plate 11 and the supporting plate 12. For example, in a case where the placement plate 11 and the supporting plate 12 are constituted by a silicon carbide-aluminum composite sintered body, it is preferable to use aluminum oxide (Al₂O₃).

The power supply terminal 15 is a rod-shaped terminal provided for applying a direct current voltage to the internal electrode 13 for electrostatic adsorption, and a material for forming the power supply terminal 15 is not particularly limited as long as it is a conductive material having excellent heat resistance, and a metal material or a conductive organic material can be used. The power supply terminal 15 is insulated from the base portion 3.

### Base Portion

The base portion 3 is provided on a lower side of the electrostatic chuck portion 2, and controls a temperature of the electrostatic chuck portion 2 to a desired temperature. The base portion 3 has a facing surface 3a facing the electrostatic chuck portion 2. The facing surface 3a is an upper surface of the base portion 3. The base portion 3 supports the electrostatic chuck portion 2 on the facing surface 3a.

The base portion 3 can also have a function of a high-frequency generation electrode. A flow path 21 through which a cooling medium such as water or an organic solvent circulates is formed inside the base portion 3. As a result, the base portion 3 cools the electrostatic chuck portion 2 and maintains a temperature of the plate-shaped sample W placed on the placement surface 2a at a desired temperature. In addition, the base portion 3 cools a cooling gas C described below and cools the plate-shaped sample W via the cooling gas C.

The base portion 3 consists of aluminum (Al) or an aluminum alloy. At least a surface of the base portion 3 exposed to plasma is preferably subjected to an anodizing treatment, or an insulating film such as alumina is preferably formed thereon. As a result, plasma resistance is improved, abnormal discharge is prevented, and thus plasma resistance stability is improved. In addition, since scratches are less likely to be made on the surface, occurrence of scratches can be prevented. It is noted that the material of the base portion 3 is not limited as long as the material is a metal material having good thermal conductivity, and for example, copper (Cu), a copper alloy, stainless steel (SUS), or the like may be employed.

### Adhesive Layer

The adhesive layer 4 includes a first adhesive portion 4a, a second adhesive portion 4b, and a surplus portion 4e. The first adhesive portion 4a is located between a lower surface 2b of the electrostatic chuck portion 2 and the facing surface 3a of the base portion 3. The first adhesive portion 4a fixes the electrostatic chuck portion 2 and the base portion 3 to each other. A thickness dimension t1 of the first adhesive portion 4a is, for example, 20 μm or more and 300 μm or less. The thickness dimension t1 may be 40 μm or more and 250 μm or less, 50 μm or more and 200 μm or less, 100 μm or more and 150 μm or less, or the like.

The second adhesive portion 4b is disposed between the lower surface 2b of the electrostatic chuck portion 2 and an upper end surface 40a of the insulator 40. In the present embodiment, a thickness dimension of the second adhesive portion 4b is substantially equal to the thickness dimension of the first adhesive portion 4a. The surplus portion 4e is a portion that is adhered to the lower surface 2b of the electrostatic chuck portion 2 in a region radially inward of an inner peripheral surface 40b of the insulator 40. The surplus portion 4e may be removed.

The adhesive layer 4 preferably consists of, for example, an adhesive having heat resistance in a temperature range of −20° C. to 150° C. As the adhesive constituting the adhesive layer 4, for example, an acrylic resin, a silicon-based resin, an epoxy-based resin, or the like is suitable. In particular, in a case where oxygen-based plasma is used, a silicon-based resin having excellent plasma resistance with respect to the oxygen-based plasma is preferable.

In the present embodiment, it is preferable that the first adhesive portion 4a and the second adhesive portion 4b consist of a single adhesive. However, each of the first adhesive portion 4a and the second adhesive portion 4b may be a portion consisting of different adhesives formed by different steps. As an example, the first adhesive portion 4a may be formed by curing a sheet-shaped adhesive, and the second adhesive portion 4b may be formed by curing a liquid adhesive.

### Cooling Gas Introduction Hole

A plurality of pin insertion holes 30B and a plurality of cooling gas introduction holes 30, which vertically pass through the electrostatic chuck portion 2, the base portion 3, and the adhesive layer 4, are provided. Each of the pin insertion holes 30B is inserted with a lift pin 22 that assists release of the plate-shaped sample W adsorbed to the placement surface 2a. A drive unit (not shown) is connected to a lower end of the lift pin 22, and drives the lift pin 22 up and down along a direction in which each of the pin insertion hole 30B passes. In the present embodiment, the pin insertion hole 30B has the same configuration as the configuration of each of the cooling gas introduction holes 30. According to the present embodiment, a step of forming the pin insertion hole 30B and the cooling gas introduction hole 30 can be commonized, and the manufacturing cost of the electrostatic chuck device 1 can be reduced. It is noted that the pin insertion hole 30B in which the lift pin 22 is installed may or may not also serve as the cooling gas introduction hole, and various selections are made depending on the design conditions.

The cooling gas introduction hole 30 is provided to supply the cooling gas C such as helium (He) toward the plate-shaped sample W placed on the electrostatic chuck portion 2. The cooling gas introduction hole 30 has a first through-hole 31 that is a portion passing through the electrostatic chuck portion 2, and a second through-hole 32 that is a portion passing through the base portion 3. That is, the electrostatic chuck portion 2 is provided with the first through-hole 31, the base portion 3 is provided with the second through-hole 32, and the first through-hole 31 and the second through-hole 32 communicate with each other to constitute the cooling gas introduction hole 30.

The first through-hole 31 and the second through-hole 32 are circular when viewed from the thickness direction Z. In the present embodiment, the direction in which the first through-hole 31 and the second through-hole 32 extend matches the thickness direction Z. However, the first through-hole 31 and the second through-hole 32 may extend in an inclined manner with respect to the thickness direction Z as long as the first through-hole 31 and the second through-hole 32 extend along the thickness direction Z. In addition, directions in which the first through-hole 31 and the second through-hole 32 extend may not be parallel to each other. The first through-hole 31 and the second through-hole 32 of the present embodiment have the same central axis line J. However, central axis lines of the first through-hole 31 and the second through-hole 32 may be shifted from each other as long as the first through-hole 31 and the second through-hole 32 communicate with each other.

The tubular insulator 40 is disposed in the second through-hole 32. An inner diameter of the second through-hole 32 is larger than an inner diameter of the first through-hole 31. A curved surface 3f is provided at an opening on an upper side of the second through-hole 32. The curved surface 3f will be described later in detail.

The second through-hole 32 has an inner peripheral surface 32a surrounding the central axis line J. In the present specification, the inner peripheral surface 32a of the second through-hole 32 means a cylindrical surface extending around the central axis line J of the second through-hole 32, and the curved surface 3f is not included in the inner peripheral surface 32a of the second through-hole 32.

### Insulator

The insulator 40 consists of, for example, ceramic. The insulator 40 has durability against plasma. As the ceramic constituting the insulator 40, ceramics consisting of one kind of material selected from aluminum nitride (AlN), aluminum oxide (Al₂O₃), silicon nitride (Si₃N₄), zirconium oxide (ZrO₂), sialon, boron nitride (BN), and silicon carbide (SiC), or composite ceramics containing two or more kinds of materials can be employed.

In the present embodiment, the upper end surface 40a of the insulator 40 is disposed on substantially the same plane as the facing surface 3a (upper surface) of the base portion 3. An outer diameter of the insulator 40 is substantially equal to an inner diameter of the second through-hole 32. An outer peripheral surface 40c of the insulator 40 is fixed to the inner peripheral surface 32a of the second through-hole 32. The insulator 40 may be fixed to the second through-hole 32 by fitting or may be fixed by adhesion.

The insulator 40 has a length that is substantially equal to a length of the second through-hole 32 and is longer than a length of the first through-hole 31. In addition, an inner diameter of the insulator 40 is larger than an inner diameter of the first through-hole 31. The inner diameter of the insulator 40 is preferably twice or more the inner diameter of the first through-hole 31. The inner diameter may be, for example, 1.2 or more times, but is not limited to these examples. The cooling gas C flows to an upper side of the inside V2 of the insulator 40 and enters the inside V1 of the first through-hole 31. The cooling gas C flows further upward from the inside V1 of the first through-hole 31 and is blown upward from an opening at an upper end. A flow path length of the cooling gas C is longer in the inside V2 of the insulator 40 than in the inside V1 of the first through-hole 31. A flow path cross-sectional area of the cooling gas C is larger in the inside V2 of the insulator 40 than in the inside V1 of the first through-hole 31. Therefore, a volume of the inside V2 of the insulator 40 is larger than a volume of the inside V1 of the first through-hole 31.

The volume of the inside V2 of the insulator 40 is preferably 5 or more times the volume of the inside V1 of the first through-hole 31. The cooling gas C is cooled by the base portion 3 through the insulator 40 while passing through the inside V2 of the insulator 40. By increasing the volume of the inside V1 of the insulator 40, the area of the inner peripheral surface 40b in contact with the cooling gas C can be increased, and the temperature of the cooling gas C can be further lowered. On the other hand, in a case where the volume of the inside V1 of the first through-hole 31 is increased, a contact area between the cooling gas C and the electrostatic chuck portion 2 is increased, heating of the cooling gas C by the electrostatic chuck portion 2 is promoted, and the temperature of the cooling gas C is increased. Further, in a case where the inner diameter of the first through-hole 31 is increased, a flow velocity of the cooling gas C blown out from the opening on the upper side of the first through-hole 31 to the lower side of the plate-shaped sample W is decreased, and the cooling efficiency by the cooling gas C may be decreased. According to the present embodiment, by setting the volume of the inside V2 of the insulator 40 to be 5 or more times the volume of the inside V1 of the first through-hole 31, the flow velocity of the cooling gas C can be ensured while lowering the temperature of the cooling gas C, and the cooling efficiency of the plate-shaped sample W can be increased.

In the present embodiment, arithmetic average roughness Ra of the inner peripheral surface 40b of the insulator 40 is preferably larger than arithmetic average roughness Ra of the inner peripheral surface 31a of the first through-hole 31. As described above, the cooling gas C passing through the cooling gas introduction hole 30 transfers heat to the base portion 3 via the inner peripheral surface 40b of the insulator 40. Therefore, by increasing the arithmetic average roughness Ra of the inner peripheral surface 40b of the insulator 40 to increase the surface area of the inner peripheral surface 40b, more heat can be transferred from the cooling gas C to the base portion 3, and the cooling efficiency of the cooling gas C can be increased. On the other hand, in a case where the arithmetic average roughness Ra of the first through-hole 31 is increased, the contact area between the cooling gas C and the electrostatic chuck portion 2 is increased, and heating of the cooling gas C by the electrostatic chuck portion 2 is promoted. In addition, in a case where the arithmetic average roughness Ra of the inner peripheral surface 31a of the first through-hole 31 is increased, particles generated during processing of the plate-shaped sample W are likely to be deposited on the inner peripheral surface 31a. The particles deposited on the inner peripheral surface 31a of the first through-hole 31 may be suddenly peeled and adversely affect the processing of the plate-shaped sample W. According to the present embodiment, it is possible to suppress the particles from being deposited on the inner peripheral surface 31a of the first through-hole 31 while ensuring a wide surface area of the inner peripheral surface of the insulator 40 and increasing the cooling efficiency of the cooling gas C.

It is preferable that the arithmetic average roughness Ra of the inner peripheral surface 40b of the insulator 40 is twice or more the arithmetic average roughness Ra of the inner peripheral surface 31a of the first through-hole 31. In this case, the cooling gas C can be sufficiently cooled by the inner peripheral surface 40b of the insulator 40, and the cooling gas introduction hole 30 that is not likely to be heated by the inner peripheral surface 31a of the first through-hole 31 can be formed. In addition, for the same reason, the arithmetic average roughness Ra of the inner peripheral surface 40b of the insulator 40 is more preferably 3 or more times the arithmetic average roughness Ra of the inner peripheral surface 31a of the first through-hole 31. The arithmetic average roughness Ra may be, for example, twice or more, however, the present invention is not limited to these examples. Further, in order to obtain each of the above-described effects, it is still more preferable that the arithmetic average roughness Ra of the inner peripheral surface 40b of the insulator 40 is 1.5 μm or more and the arithmetic average roughness Ra of the inner peripheral surface 31a of the first through-hole 31 is 0.5 μm or less.

The first through-hole 31 of the present embodiment is mainly formed by cutting. In order to improve the surface properties of the inner peripheral surface 31a of the first through-hole 31, it is preferable to perform fine finishing processing at the time of forming the first through-hole 31. Furthermore, surface properties of the inner peripheral surface 31a may be improved by performing brush polishing, buffing, or the like after formation of the first through-hole 31.

### Curved Surface

As shown in FIG. 2, the base portion 3 has the curved surface 3f located at an opening of the second through-hole 32. The curved surface 3f is continuous with the facing surface 3a (upper surface (flat surface portion)). The curved surface 3f has a uniform cross-sectional shape and extends in a peripheral direction around the central axis line J. As will be described later, the curved surface 3f may have a smooth curved surface having no recess when viewed from a cross-section passing through the central axis J. It is preferable that a hole formed by the curved surface 3f is circular in plan view and is continuously increased toward the upper side.

In the following description of the curved surface 3f, a radial direction with respect to the central axis line J is simply referred to as a “radial direction”, and a peripheral direction with respect to the central axis line J may be simply referred to as a “peripheral direction”.

The curved surface 3f of the present embodiment connects the facing surface 3a and the inner peripheral surface 32a of the second through-hole 32 to each other with a uniform radius of curvature. The curved surface 3f is smoothly connected to the facing surface 3a at an upper end portion and is smoothly connected to the inner peripheral surface 32a at a lower end portion.

The outer peripheral surface 40c of the insulator 40 faces an inner side of the curved surface 3f in the radial direction. A part of the first adhesive portion 4a of the adhesive layer 4 enters between the curved surface 3f and the inner peripheral surface 40b of the insulator 40. As a result, the curved surface 3f is covered with the first adhesive portion 4a. In addition, a portion of the outer peripheral surface 40c of the insulator 40, which faces the curved surface 3f in the radial direction, is also covered with the first adhesive portion 4a.

The base portion 3 and the adhesive layer 4 consist of materials having different thermal expansion coefficients. More specifically, the base portion 3 consists of a metal material having high thermal conductivity, and the adhesive layer 4 consists of a resin. Therefore, a thermal stress is applied to an interface between the adhesive layer 4 and the base portion 3 due to a temperature change, and there is a possibility that the adhesive layer 4 may be peeled from the interface. In a case where the adhesive layer is peeled, a part of the metal base is exposed in a He gas flow path, and this can be a starting point/ending point of discharge. In particular, corner portions of a metal (general corner portions and the like) are likely to concentrate an electric field and are likely to be the starting point/ending point of discharge. In addition, since the thermal stress is also likely to be concentrated on corner portions provided in the base portion 3, peeling is most likely to occur with the corner portions of the base portion 3 set as a starting point. Such corner portions have a point (apex) at which two straight lines (surfaces) are in contact with each other when viewed from a cross-section.

On the other hand, according to the present embodiment, in the facing surface 3a of the base portion 3 which is in contact with the adhesive layer 4, a corner portion of an opening edge of the second through-hole 32 is rounded and the curved surface 3f is formed. That is, the corner portion has a convex or substantially convex curve in a cross-section. As a result, a corner portion that is likely to be a peeling starting point is not formed at an interface where the adhesive layer 4 and the base portion 3 are adhered to each other, and peeling of the adhesive layer 4 with respect to the base portion 3 can be suppressed.

In a case where peeling occurs at the interface between the base portion 3 and the adhesive layer 4, there is a possibility that discharge occurs from the base portion 3. In addition, since electric charge is likely to be concentrated on the corner portion, in a case where the peeled portion in the base portion 3 is the corner portion, the discharge is more likely to occur. According to the present embodiment, the corner portion of the base portion 3 is formed as the curved surface 3f, and thus, the occurrence of discharge from the base portion 3 can be suppressed. In general, it is known that in a case where a diameter of the second through-hole 32 forming the cooling gas introduction hole 30 is increased, discharge from the base portion 3 is likely to occur. In the present embodiment, since a configuration in which the discharge from the base portion 3 can be suppressed is employed, the diameter of the second through-hole 32 can be increased. That is, according to the present embodiment, it is possible to employ a configuration in which the diameter of the second through-hole 32 is increased, the volume of the inside V2 of the insulator 40 is increased, and the cooling gas C is sufficiently cooled in the cooling gas introduction hole 30, and as a result, it is possible to increase the cooling efficiency of the plate-shaped sample W by the cooling gas C.

In the present embodiment, the entire surface of the curved surface 3f is covered with the first adhesive portion 4a. For example, an example in which a space between the curved surface 3f and the lower surface 2b of the electrostatic chuck portion 2 is filled with the first adhesive portion 4a has been described. It is noted that in a case where the base portion 3 and the electrostatic chuck portion 2 are adhered to each other through the adhesive layer 4, the first adhesive portion 4a enters a gap between the curved surface 3f and the outer peripheral surface 40c of the insulator 40. Therefore, the first adhesive portion 4a may not cover the entire curved surface 3f, and only a part of the curved surface 3f, for example, only an upper region of the curved surface 3f may be covered with the first adhesive portion 4a. However, even in such a case, in a case where the first adhesive portion 4a covers at least a boundary portion between the facing surface 3a and the curved surface 3f, an effect of suppressing peeling of the adhesive layer 4 with respect to the base portion 3 from the boundary portion can be obtained to a certain extent or more.

In the present embodiment, it is preferable that the radius of curvature R of the curved surface 3f in a cross-section (a cross-section including the central axis J) along the central axis line J is larger than the thickness dimension d1 of the internal electrode 13 for electrostatic adsorption. As a result, the radius of curvature R of the curved surface 3f can be set to a sufficient size for suppressing the peeling of the adhesive layer 4. It is noted that the radius of curvature may be obtained, for example, by observing a cross-section including the central axis line J of the base portion 3 and taking a captured image.

In the present embodiment, it is preferable that the radius of curvature R of the curved surface 3f in a cross-section along the central axis line J is larger than the thickness dimension t1 of the first adhesive portion 4a. As a result, the radius of curvature R of the curved surface 3f can be set to a sufficient size for suppressing the peeling of the adhesive layer 4. In addition, by setting the radius of curvature R within such a range, in a case where the base portion 3 and the electrostatic chuck portion 2 are adhered to each other, the first adhesive portion 4a is formed while the adhesive that forms the adhesive layer 4 smoothly spreads from the facing surface 3a (upper surface (flat surface portion)) to the curved surface 3f. Therefore, the first adhesive portion 4a can cover the boundary portion between the facing surface 3a and the curved surface 3f without unevenness, and it is possible to further reduce concentration of stress on the corner portion, and it is possible to form the first adhesive portion 4a homogeneously because air bubbles are unlikely to occur at the interface between the adhesive layer 4 and the base portion 3.

It is preferable that the radius of curvature R of the curved surface 3f in the cross-section along the central axis line J is larger than the thickness dimension d1 of the internal electrode 13 for electrostatic adsorption so that the electric field concentrated in this portion is dispersed, and specifically, it is preferable that the radius of curvature R is 10 μm or more. By setting the radius of curvature R of the curved surface 3f to 10 μm or more, stress due to thermal stress is less likely to be concentrated on the curved surface 3f, and peeling of the adhesive layer 4 on the curved surface 3f can be suppressed, and the concentrated electric field can be dispersed, and foreign matter charged particles that fly/are adsorbed and the like can be dispersed. In addition, the radius of curvature R of the curved surface 3f is preferably larger than the thickness dimension t1 so that an adhesive portion layer having the thickness dimension t1 is stably continuous with the curved surface 3f, and specifically, for example, it is more preferable that the radius of curvature R is 100 μm or more and still more preferably 1000 μm or more. In a case where the radius of curvature R is 100 μm or more or 1000 μm or more, peeling of the adhesive layer 4 on the curved surface 3f can be more reliably suppressed, and the curved surface 3f can be easily and stably formed.

It is noted that in the present embodiment, a case where the radius of curvature R of the curved surface 3f is constant over the entire curved surface 3f has been described, but the radius of curvature R of the curved surface 3f may continuously change along the radial direction of the central axis line J. That is, the curved surface 3f may be constituted by a complex curved surface such as an elliptic curved surface or a free curved surface. Even in this case, the minimum radius of curvature R among the radii of curvature R of each portion of the curved surface 3f may fall within the above-described range.

The curved surface 3f can be formed by performing buffing or the like on the corner portion provided at the opening edge of the second through-hole 32 after the second through-hole 32 is formed by a drill or the like. In addition, the curved surface 3f may be formed by using a dedicated cutting tool for additionally machining the opening edge of the second through-hole 32 into a curved shape.

### Modification Example of Curved Surface

In the above-described embodiment, a case where the curved surface 3f is directly connected to the facing surface 3a and the inner peripheral surface 32a of the second through-hole 32 has been described. However, the curved surface may not be connected to the inner peripheral surface 32a of the second through-hole 32 as long as the curved surface is connected to the facing surface 3a. In addition, the number of curved surfaces is not limited to one and may be, for example, two.

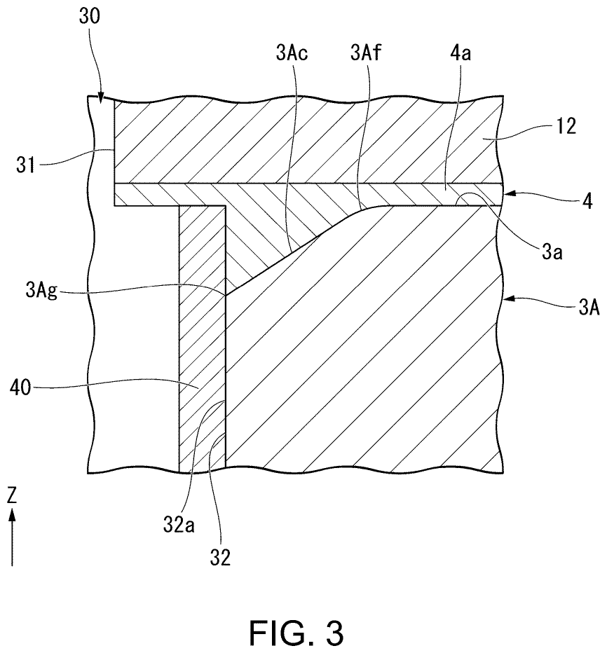

FIG. 3 is a schematic cross-sectional view of a curved surface 3Af showing a modification example that can be employed in the first embodiment. It is noted that constituent elements having the same aspect as the constituent elements of the above-described embodiment are denoted by the same reference numerals, and the description thereof is omitted. In addition, the curved surface 3Af of the present modification example can be employed not only in the first embodiment but also in all embodiments described below.

A chamfered portion 3Ac is provided between the facing surface 3a of a base portion 3A of the present modification example and the first through-hole 31. The chamfered portion 3Ac has a uniform cross-sectional shape and extends in the peripheral direction around the central axis line J. The chamfered portion 3Ac is located at an opening on the upper side of the second through-hole 32, and the diameter of the second through-hole 32 increases toward the upper side. The chamfered portion 3Ac may have a smooth surface without a protrusion or a recess.

The curved surface 3Af of the present modification example is provided at a boundary portion between the facing surface 3a and the chamfered portion 3Ac. The curved surface 3Af is continuous with the facing surface 3a and the chamfered portion 3Ac. Even in a case where the curved surface 3Af has such a configuration, it is possible to suppress a corner portion from being provided at the interface between the first adhesive portion 4a and the facing surface 3a, and it is possible to suppress the first adhesive portion 4a from being peeled from the facing surface 3a.

It is noted that in the modification example shown in FIG. 3, a corner portion is formed at a boundary portion 3Ag between the chamfered portion 3Ac and the inner peripheral surface 32a of the second through-hole 32. The boundary portion 3Ag may also be a curved surface similar to the boundary portion with the facing surface 3a.

### Semiconductor Manufacturing Apparatus

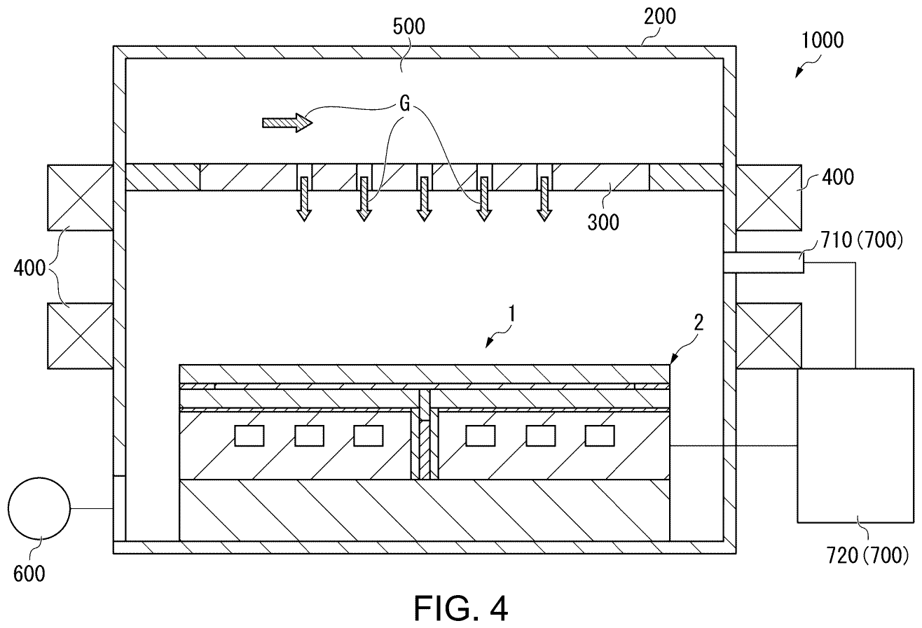

FIG. 4 is a view showing a semiconductor manufacturing apparatus 1000 including the above-described electrostatic chuck device 1. The semiconductor manufacturing apparatus 1000 includes the electrostatic chuck device 1, a vacuum chamber 200, an upper electrode 300, a magnet 400, gas supply means 500, a vacuum pump 600, and a plasma stabilization system 700.

The vacuum chamber 200 accommodates the electrostatic chuck device 1 and is used as a reaction field where a plasma treatment is performed at the inside thereof. The vacuum chamber 200 can employ a well-known configuration used for a semiconductor manufacturing apparatus. The vacuum chamber 200 includes a gate (not shown) into and from which a plate-shaped sample is put and taken out.

The upper electrode 300 is a counter electrode that is accommodated in the vacuum chamber 200 and is used in combination with the electrostatic chuck device 1 when a plasma is generated in the vacuum chamber 200. The upper electrode 300 is connected to a power supply (not shown).

The magnet 400 is disposed around the vacuum chamber 200 and generates a longitudinal magnetic field in a space between the upper electrode 300 and the electrostatic chuck device 1 in the vacuum chamber 200.

The gas supply means 500 supplies a plasma gas G into the vacuum chamber 200. The gas supply means 500 supplies the plasma gas G into the vacuum chamber 200 from, for example, gas holes provided in the upper electrode 300.

The vacuum pump 600 exhausts a gas in the vacuum chamber 200 and controls an atmosphere for generating plasma. The vacuum pump 600 is connected to, for example, a region of the vacuum chamber 200 below the electrostatic chuck device 1.

The plasma stabilization system 700 detects various external factors that cause a state of plasma generated in the semiconductor manufacturing apparatus 1000 to fluctuate, and compensates for the external factors, thereby stabilizing the state of the plasma. The plasma stabilization system 700 includes a detector 710 and a control unit 720 that controls the semiconductor manufacturing apparatus 1000 based on a detection result by the detector 710.

The detector 710 directly or indirectly detects the state of the plasma in the vacuum chamber 200. The number of the detectors 710 may be one or plural. Examples of items detected by the detector 710 include the degree of vacuum in the vacuum chamber 200, a color of the plasma, a temperature of the plasma, capacitance between the upper electrode 300 and an internal electrode (not shown) for generating plasma in the electrostatic chuck device 1, inductance between the upper electrode 300 and the internal electrode for generating plasma, and the like.

The control unit 720 controls the semiconductor manufacturing apparatus 1000 based on a detection value of each of the items detected by the detector 710 or the amount of change in the detection value per unit time. The control unit 720 stores a correspondence between the detection value of the above-described items and the state of the plasma generated in the vacuum chamber 200 in advance. The control unit 720 performs feedback control on the semiconductor manufacturing apparatus 1000 such that the state of the plasma is within a predetermined range based on the detection value and the above-described correspondence. Examples of the items on which the feedback control is performed include a temperature, the degree of vacuum, and a bias voltage in the semiconductor manufacturing apparatus.

Due to these items, the plasma stabilization system 700 can suppress a long-term fluctuation in the plasma state of the semiconductor manufacturing apparatus 1000 to stabilize the state.

Such a plasma stabilization system is effective in suppressing the fluctuation in the plasma state in the entire manufacturing process using the semiconductor manufacturing apparatus. On the other hand, the plasma stabilization system has no effect of suppressing the state fluctuation with respect to a fluctuation factor that occurs for an extremely short time such as abnormal discharge in wafer processing.

On the other hand, since the semiconductor manufacturing apparatus 1000 includes the above-described electrostatic chuck device 1, abnormal discharge that occurs during wafer processing can be suppressed. Therefore, the semiconductor manufacturing apparatus 1000 includes the plasma stabilization system 700, and thus the plasma can be stabilized in a long term and in a short term.

It is noted that the control unit 720 may be a unique configuration of the plasma stabilization system 700, or a control device that controls the semiconductor manufacturing apparatus 1000 may also function as the control unit 720.

In the semiconductor manufacturing apparatus 1000, for example, a tendency of the attachment of charged foreign particles to a side peripheral surface of the electrostatic chuck portion 2 may vary depending on a position of an exhaust port of the vacuum chamber 200 (connection position of the vacuum pump 600). When the above-described tendency is empirically determined in the semiconductor manufacturing apparatus 1000, the electrostatic chuck portion 2 may employ the configuration where the attachment of the charged foreign particles is suppressed, for example, the arithmetic average roughness Ra of the side peripheral surface at a position where the charged foreign particles are likely to be attached is less than that of other side peripheral surfaces.

The semiconductor manufacturing apparatus 1000 according to the present embodiment includes the above-described electrostatic chuck device 1, and thus can suppress occurrence of dielectric breakdown (discharge).

In addition, in the semiconductor manufacturing apparatus 1000, abnormal discharge (the short-term fluctuation in plasma) can be suppressed by the electrostatic chuck device 1, and the long-term fluctuation in plasma can be suppressed by the plasma stabilization system 700. Therefore, a stable plasma treatment can be performed, and a semiconductor manufacturing apparatus with an improved yield can be obtained.

### Second Embodiment

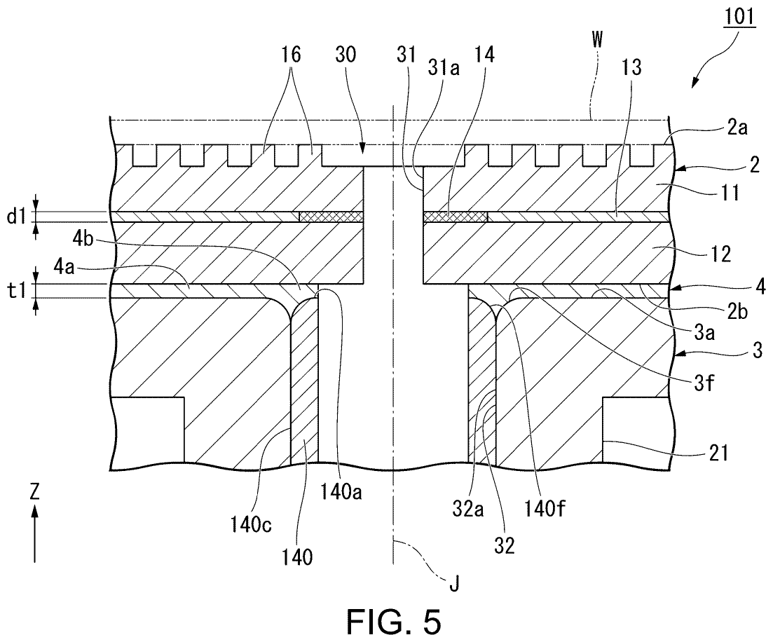

FIG. 5 is an enlarged cross-sectional view of an electrostatic chuck device 101 of a second embodiment. The electrostatic chuck device 101 of the second embodiment is different from the first embodiment mainly in that an insulator curved surface 140f is provided at an upper end portion of the insulator 140.

It is noted that constituent elements having the same aspect as the constituent elements of the above-described embodiment are denoted by the same reference numerals, and the description thereof is omitted.

The electrostatic chuck device 101 includes the electrostatic chuck portion 2, the base portion 3, the adhesive layer 4, and the insulator 140. In addition, the electrostatic chuck device 101 is provided with the plurality of cooling gas introduction holes 30 that vertically pass through the electrostatic chuck portion 2, the base portion 3, and the adhesive layer 4. The cooling gas introduction hole 30 has a first through-hole 31 that is a portion passing through the electrostatic chuck portion 2, and a second through-hole 32 that is a portion passing through the base portion 3. The base portion 3 is provided with the curved surface 3f that is located at the opening of the second through-hole 32 and is connected to the facing surface 3a.

As in the first embodiment, a tubular insulator 140 is disposed in the second through-hole 32. The insulator 140 extends along the thickness direction Z (that is, the vertical direction). An upper end of the insulator 140 is located on the same plane as the facing surface 3a of the base portion 3.

In the insulator 140 of the present embodiment, the insulator curved surface 140f is provided at a boundary portion between the upper end surface 140a and the outer peripheral surface 140c. The insulator curved surface 140f connects the upper end surface 140a and the outer peripheral surface 140c to each other with a uniform radius of curvature. The insulator curved surface 140f is smoothly connected to the upper end surface 140a at an upper end portion and is smoothly connected to the outer peripheral surface 140c at a lower end portion. It is preferable that an outer diameter of the insulator 140 in the insulator curved surface 140f decreases as approaching the supporting plate 12.

According to the present embodiment, it is possible to suppress the corner portion of the insulator 140 from being formed at the interface between the insulator 140 and the adhesive layer 4. Therefore, even in a case where the thermal stress is applied to the interface between the insulator 140 and the adhesive layer 4, the adhesive layer 4 is less likely to be peeled from the insulator 140. In addition, according to the present embodiment, the curved surface 3f is provided on the insulator 140, so that a gap between the curved surface 3f of the base portion 3 and the insulator curved surface 140f of the insulator 140 is secured to be wide, and the gap can be sufficiently filled with the adhesive constituting the adhesive layer 4. As a result, the first adhesive portion 4a of the adhesive layer 4 can cover the curved surface 3f of the base portion 3 in a wider range, and the peeling of the adhesive layer 4 and the base portion 3 can be more effectively suppressed.

In the present embodiment, in the insulator curved surface 140f, a radius of curvature of the insulator curved surface 140f in the cross-section along the central axis line J matches the radius of curvature of the curved surface 3f. However, the radius of curvature of the insulator curved surface 140f and the radius of curvature of the curved surface 3f do not necessarily have to match each other. It is preferable that the radius of curvature of the insulator curved surface 140f is in the same numerical range as in the radius of curvature of the curved surface 3f. That is, it is preferable that the radius of curvature of the insulator curved surface 140f is larger than the thickness dimension d1 of the internal electrode 13 for electrostatic adsorption. In addition, it is preferable that the radius of curvature of the insulator curved surface 140f is larger than the thickness dimension t1 of the first adhesive portion 4a. More specifically, the radius of curvature of the insulator curved surface 140f is preferably 10 μm or more, more preferably 100 μm or more, and still more preferably 1,000 μm or more. As a result, the peeling of the adhesive layer 4 on the insulator curved surface 140f can be suppressed while suppressing the mixing of air bubbles into the adhesive layer 4 during assembly.

### Third Embodiment

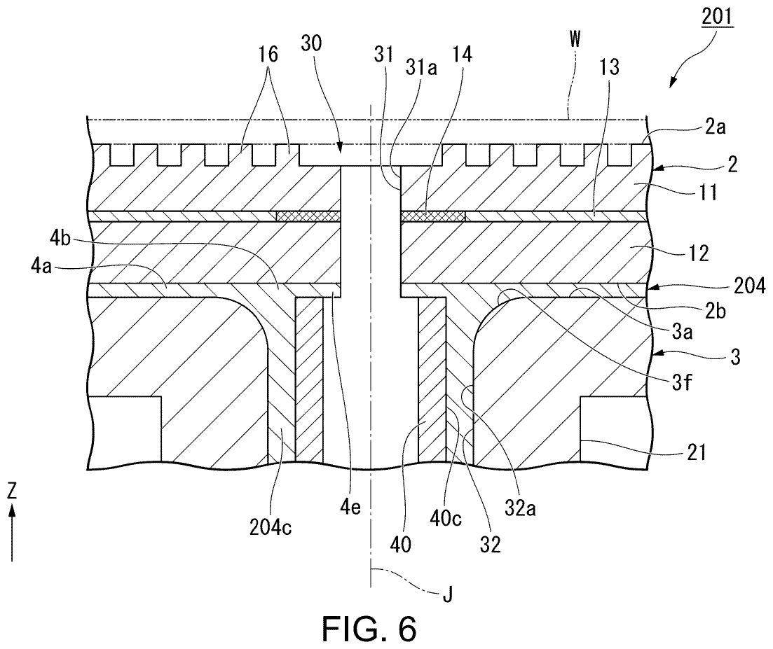

FIG. 6 is an enlarged cross-sectional view of an electrostatic chuck device 201 of a third embodiment. The electrostatic chuck device 201 of the third embodiment is different from the electrostatic chuck device of the first embodiment mainly in that a third adhesive portion 204c of an adhesive layer 204 is provided between the outer peripheral surface 40c of the insulator 40 and the inner peripheral surface 32a of the second through-hole 32. It is noted that constituent elements having the same aspect as the constituent elements of the above-described embodiment are denoted by the same reference numerals, and the description thereof is omitted.

The electrostatic chuck device 201 includes the electrostatic chuck portion 2, the base portion 3, the adhesive layer 204, and the insulator 40. In addition, the electrostatic chuck device 201 is provided with the plurality of cooling gas introduction holes 30 that vertically pass through the electrostatic chuck portion 2, the base portion 3, and the adhesive layer 204. The cooling gas introduction hole 30 has a first through-hole 31 that is a portion passing through the electrostatic chuck portion 2, and a second through-hole 32 that is a portion passing through the base portion 3. The base portion 3 is provided with the curved surface 3f that is located at the opening of the second through-hole 32 and is connected to the facing surface 3a.

As in the first embodiment, the tubular insulator 40 is disposed in the second through-hole 32. The insulator 40 of the present embodiment is adhered and fixed to the inner peripheral surface 32a of the second through-hole 32 by the third adhesive portion 204c of the adhesive layer 204. That is, the adhesive layer 204 of the present embodiment includes the third adhesive portion 204c in addition to the first adhesive portion 4a, the second adhesive portion 4b, and the surplus portion 4e.

The third adhesive portion 204c is interposed between the inner peripheral surface 32a of the second through-hole 32 and the outer peripheral surface 40c of the insulator 40. The third adhesive portion 204c fixes the insulator 40 to the inner peripheral surface 32a of the second through-hole 32. The third adhesive portion 204c may be formed of the same type of adhesive as the first adhesive portion 4a and the second adhesive portion 4b, or may be formed of a different type of adhesive.

The third adhesive portion 204c covers the inner peripheral surface 32a of the second through-hole 32. Therefore, the adhesive layer 204 can continuously cover the facing surface 3a, the curved surface 3f, and the inner peripheral surface 32a of the base portion 3 without interruption. According to the present embodiment, the peeling starting point is less likely to occur at the interface between the adhesive layer 204 and the base portion 3, and the peeling of the adhesive layer 204 can be suppressed. In particular, in the present embodiment, since the adhesive layer 204 covers the entire curved surface 3f, even in a case where the thermal stress is applied to the interface between the base portion 3 and the adhesive layer 204, the peeling of the adhesive layer 204 on the curved surface 3f can be effectively suppressed.

It is noted that the third adhesive portion 204c described in the present embodiment may be provided in each adhesive layer in other embodiments as well as the present embodiment.

### Fourth Embodiment

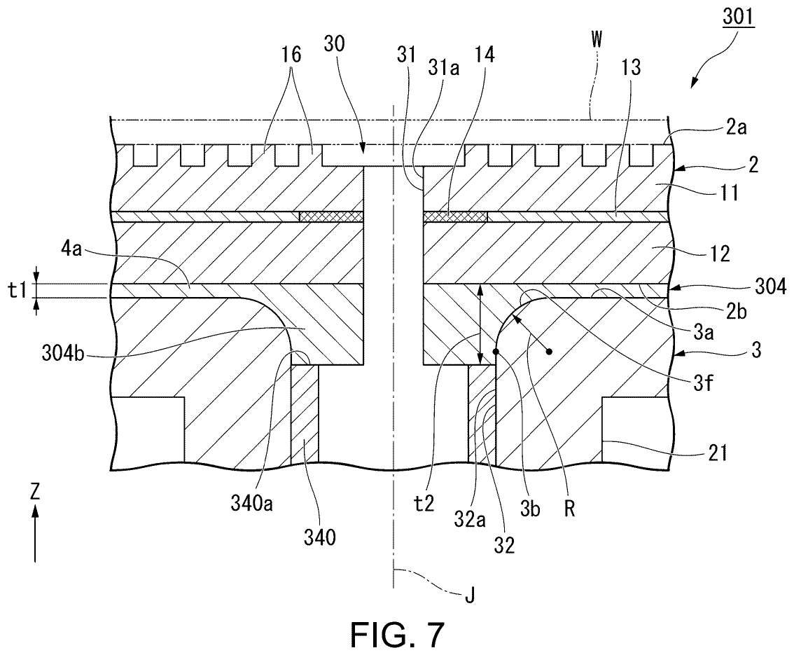

FIG. 7 is an enlarged cross-sectional view of an electrostatic chuck device 301 of a fourth embodiment. The electrostatic chuck device 301 of the fourth embodiment is different from the first embodiment mainly in a position of an upper end portion of an insulator 340. It is noted that constituent elements having the same aspect as the constituent elements of the above-described embodiment are denoted by the same reference numerals, and the description thereof is omitted.

The electrostatic chuck device 301 includes the electrostatic chuck portion 2, the base portion 3, an adhesive layer 304, and an insulator 340. In addition, in the electrostatic chuck device 301, a plurality of cooling gas introduction holes 30 that vertically pass through the electrostatic chuck portion 2, the base portion 3, and the adhesive layer 304 are provided. The cooling gas introduction hole 30 has a first through-hole 31 that is a portion passing through the electrostatic chuck portion 2, and a second through-hole 32 that is a portion passing through the base portion 3. The base portion 3 is provided with the curved surface 3f that is located at the opening of the second through-hole 32 and is connected to the facing surface 3a.

As in the first embodiment, a tubular insulator 340 is disposed in the second through-hole 32. The upper end surface 340a of the insulator 340 of the present embodiment is located below the facing surface 3a of the base portion 3. An upper end surface 340a of the insulator 340 is located below the end portion 3b of the curved surface 3f on a lower side in the thickness direction Z.

As in the first embodiment, the adhesive layer 304 includes a second adhesive portion 304b that is located between the upper end surface 340a of the insulator 340 and the electrostatic chuck portion 2. The second adhesive portion 304b of the present embodiment covers the entire curved surface 3f. Therefore, even in a case where the thermal stress is applied to the interface between the base portion 3 and the adhesive layer 304, the peeling of the adhesive layer 304 on the curved surface 3f can be effectively suppressed.

In a case where the curved surface 3f has a uniform radius of curvature R over the entire surface, the entire curved surface 3f can be sufficiently covered in a case where the thickness dimension t2 of the second adhesive portion 304b is larger than the sum of the radius of curvature R of the curved surface 3f and the thickness dimension t1 of the first adhesive portion 4a. In addition, in a case where the thickness dimension t2 of the second adhesive portion 304b is twice or more the thickness dimension t1 of the first adhesive portion 4a, the second adhesive portion 304b can cover the curved surface 3f to the extent that peeling on the curved surface 3f can be suppressed.

### Fifth Embodiment

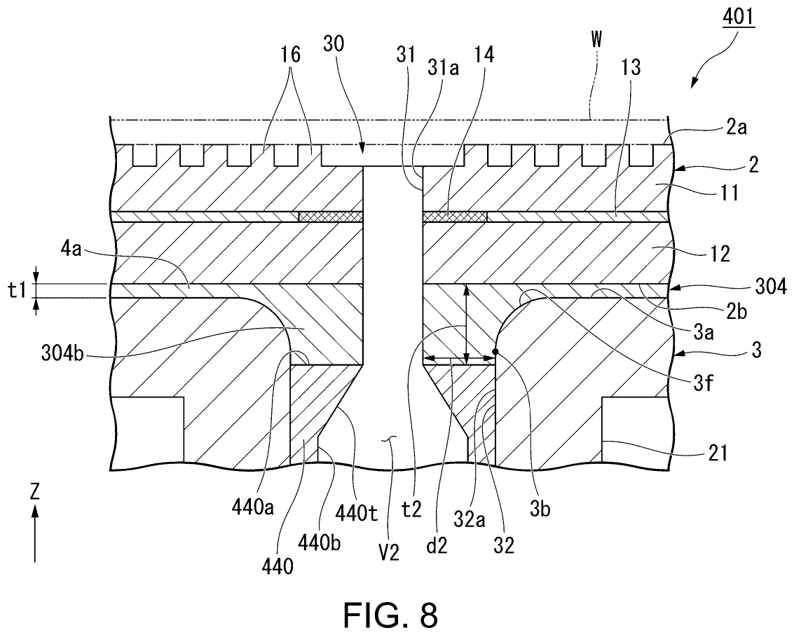

FIG. 8 is an enlarged cross-sectional view of an electrostatic chuck device 401 of a fifth embodiment. The electrostatic chuck device 401 of the fifth embodiment is similar to the electrostatic chuck device of the fourth embodiment, and is different from the electrostatic chuck device of the fourth embodiment mainly in that a tapered surface 440t is provided on an inner peripheral surface 440b of an insulator 440. It is noted that constituent elements having the same aspect as the constituent elements of the above-described embodiment are denoted by the same reference numerals, and the description thereof is omitted.

The electrostatic chuck device 401 includes the electrostatic chuck portion 2, the base portion 3, the adhesive layer 304, and the insulator 440. In addition, in the electrostatic chuck device 401, the plurality of cooling gas introduction holes 30 that vertically pass through the electrostatic chuck portion 2, the base portion 3, and the adhesive layer 304 are provided. The cooling gas introduction hole 30 has a first through-hole 31 that is a portion passing through the electrostatic chuck portion 2, and a second through-hole 32 that is a portion passing through the base portion 3. The base portion 3 is provided with the curved surface 3f that is located at the opening of the second through-hole 32 and is connected to the facing surface 3a.

As in the fourth embodiment, the insulator 440 having a tubular shape is disposed in the second through-hole 32. An upper end surface 440a of the insulator 440 of the present embodiment is located below the facing surface 3a of the base portion 3. The upper end surface 440a of the insulator 440 is located below the end portion 3b of the curved surface 3f on the lower side in the thickness direction Z. Therefore, the second adhesive portion 304b of the adhesive layer 304 covers the entire curved surface 3f, and the peeling of the adhesive layer 304 on the curved surface 3f is suppressed.

In the present embodiment, the tapered surface 440t of which a diameter (inner diameter) decreases toward the upper side is provided on the inner peripheral surface 440b of the insulator 440. The inner diameter of the upper end surface 440a of the insulator 440 is substantially equal to the inner diameter of the first through-hole 31. Therefore, the second adhesive portion 304b disposed between the upper end surface 440a of the insulator 440 and the electrostatic chuck portion 2 in the adhesive layer 304 can be made thick in the radial direction of the second through-hole 32. That is, an interface between the insulator 440 and the second adhesive portion 304b can be made longer in the radial direction, and thus a discharge path of the base portion 3 can be made longer, and discharge from the base portion 3 can be suppressed.

In the present embodiment, it is preferable that the dimension d2 of the second adhesive portion 304b in the radial direction of the second through-hole 32 is larger than the thickness dimension t1 of the first adhesive portion 4a. In this case, the interface between the insulator 440 and the second adhesive portion 304b is lengthened, and thus discharge from the base portion 3 can be effectively suppressed.

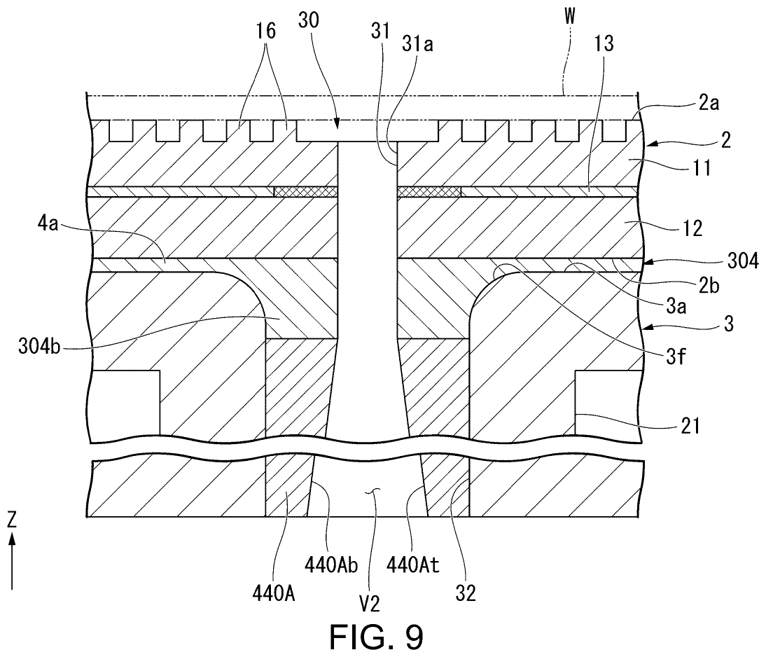

The tapered surface 440t of the present embodiment is provided in an upper region including an upper end of the entire length of the inner peripheral surface 440b of the insulator 440. However, the region where the tapered surface 440t is provided is not limited to the present embodiment. For example, as a modification example shown in FIG. 9, a tapered surface 440At may be provided on the entire length of an inner peripheral surface 440Ab of the insulator 440A.

By providing the tapered surfaces 440t and 440At on the inner peripheral surfaces 440b and 440Ab of the insulators 440 and 440A, the flow path cross-sectional area of the cooling gas C flowing upward in the inside V2 of the insulators 440 and 440A can be gradually reduced toward the first through-hole 31. In particular, as shown in the modification example, in a case where the tapered surface 440At is provided over the entire length of the insulator 440, a taper angle of the tapered surface 440At can be reduced, and the flow path cross-sectional area of the cooling gas C can be further reduced. As a result, a flow path resistance of the cooling gas C can be reduced, and the flow velocity of the cooling gas C blown toward the plate-shaped sample W can be increased.

The configuration of the cooling gas introduction hole 30 of the present embodiment can also be applied to the pin insertion hole 30B shown in FIG. 1. In this case, the tapered surfaces 440t and 440At function as guides in a case where the lift pin 22 rises in the pin insertion hole 30B.

Hereinabove, various embodiments of the present invention have been described. However, the configurations of the embodiments, a combination thereof, and the like are exemplary, and additions, omissions, replacements and other changes can be made for the configurations within a range not departing from the scope of the present invention. For example, unless otherwise specified, conditions such as materials, positions, ratios, amounts, types, numbers, sizes, and values may be changed, added, or omitted as necessary. In the embodiments, preferred conditions or examples may be exchanged or shared with each other. In addition, the present invention is not limited to only the embodiments.

For example, in the above-described embodiment, a heater element that heats the electrostatic chuck portion may be embedded in the adhesive layer. In addition, the heater element may be located inside the electrostatic chuck portion or inside the base portion.

In addition, the configuration of the cooling gas introduction hole 30 described in the above-described embodiment can also be applied to the pin insertion hole 30B, and can also be applied to other through-holes.

### INDUSTRIAL APPLICABILITY

The present invention provides an electrostatic chuck device in which cooling efficiency is improved.

### REFERENCE SIGNS LIST

1, 101, 201, 301, 401 Electrostatic chuck device
2 Electrostatic chuck portion
2a Placement surface
2b Lower surface
3, 3A Base portion
3a Facing surface
3b End portion
3f, 3Af Curved surface
3Ac Chamfered portion
3Ag Boundary portion
4, 204, 304 Adhesive layer
4a First adhesive portion
4b, 304b Second adhesive portion
4e Surplus portion
11 Placement plate
12 Supporting plate
13 Internal electrode for electrostatic adsorption
14 Insulating material layer
15 Power supply terminal
16 Protrusion portion
21 Flow path
22 Lift pin
30 Cooling gas introduction hole
30B Pin insertion hole
31 First through-hole
31a, 32a, 40b, 440b, 440Ab Inner peripheral surface
32 Second through-hole
40, 140, 340, 440, 440A Insulator
40a, 140a, 340a, 440a Upper end surface
40c, 140c Outer peripheral surface
140f Insulator curved surface
200 Vacuum chamber
204c Third adhesive portion
300 Upper electrode
400 Magnet
440t, 440At Tapered surface
500 Gas supply portion
600 Vacuum pump
700 Plasma stabilization system
710 Detector
720 Control unit
1000 Semiconductor manufacturing apparatus
C Cooling gas
d1, t1, t2 Thickness dimension
d2 Dimension
G Plasma gas
J Central axis line
R Radius of curvature
V1, V2 Inside
W Plate-shaped sample
Z Thickness direction

1. An electrostatic chuck device comprising:
a plate-shaped electrostatic chuck portion which supports a plate-shaped sample on a placement surface facing one side in a thickness direction and in which an internal electrode for electrostatic adsorption is built-in;
a base portion that supports the electrostatic chuck portion from an other side in the thickness direction and cools the electrostatic chuck portion;
an adhesive layer that is located between the electrostatic chuck portion and the base portion and includes a first adhesive portion that fixes the electrostatic chuck portion and the base portion; and
a tubular insulator,
wherein the electrostatic chuck portion is provided with a first through-hole extending along the thickness direction,
the base portion is provided with a second through-hole extending along the thickness direction and communicating with the first through-hole,
the insulator is disposed in the second through-hole,
the base portion has a facing surface facing the electrostatic chuck portion, and
the base portion has a curved surface that is located at an opening of the second through-hole and is connected to the facing surface.

2. The electrostatic chuck device according to claim 1,
wherein a radius of curvature of the curved surface in a cross-section along a central axis line of the second through-hole is larger than a thickness dimension of the internal electrode for electrostatic adsorption.

3. The electrostatic chuck device according to claim 1,
wherein a radius of curvature of the curved surface in a cross-section along a central axis line of the second through-hole is larger than a thickness dimension of the first adhesive portion.

4. The electrostatic chuck device according to claim 1,
wherein a radius of curvature of the curved surface in a cross-section along a central axis line of the second through-hole is 10 μm or more.

5. The electrostatic chuck device according to claim 1,
wherein the adhesive layer covers the entire curved surface.

6. The electrostatic chuck device according to claim 5,
wherein an end surface of the insulator on the one side in the thickness direction is located on the other side in the thickness direction with respect to an end portion of on the other side of the curved surface, and
the adhesive layer includes a second adhesive portion that is located between the end surface of the insulator and the electrostatic chuck portion.

7. The electrostatic chuck device according to claim 6,
wherein a thickness dimension of the second adhesive portion is twice or more a thickness dimension of the first adhesive portion.

8. The electrostatic chuck device according to claim 6,
wherein a dimension of the second adhesive portion in a radial direction of the second through-hole is larger than a thickness dimension of the first adhesive portion.

9. The electrostatic chuck device according to claim 5,
wherein the adhesive layer includes a third adhesive portion that is interposed between an inner peripheral surface of the second through-hole and an outer peripheral surface of the insulator and that fixes the insulator to the inner peripheral surface of the second through-hole.

10. The electrostatic chuck device according to claim 1,
wherein a volume inside the insulator is 5 or more times a volume inside the first through-hole.

11. The electrostatic chuck device according to claim 1,
wherein arithmetic average roughness Ra of an inner peripheral surface of the insulator is larger than arithmetic average roughness Ra of an inner peripheral surface of the first through-hole.

12. The electrostatic chuck device according to claim 11,
wherein the arithmetic average roughness Ra of the inner peripheral surface of the insulator is twice or more the arithmetic average roughness Ra of the inner peripheral surface of the first through-hole.

13. The electrostatic chuck device according to claim 11,
wherein the arithmetic average roughness Ra of the inner peripheral surface of the insulator is 1.5 μm or more, and
the arithmetic average roughness Ra of the inner peripheral surface of the first through-hole is 0.5 μm or less.

14. The electrostatic chuck device according to claim 1,
wherein a tapered surface of which a diameter decreases toward the one side in the thickness direction is provided on an inner peripheral surface of the insulator.

15. The electrostatic chuck device according to claim 1,
wherein a chamfered portion is provided at a boundary portion between the facing surface and an inner peripheral surface of the second through-hole, and
the curved surface is connected to the facing surface and the chamfered portion.
